(19) United States
(12) Patent Application Publication
(10) Pub. No.: US 2005/0109608 A1
(43) Pub. Date: May 26, 2005

(54) Method of improving thermal stability for cobalt salicide

(75) Inventor: Chin-Ta Su, Hsinchu (TW)

Correspondence Address: MARTINE PENILLA & GENCARELLA, LLP, 710 LAKEWAY DRIVE, SUITE 200, SUNNYVALE, CA, 94085, US

(73) Assignee: Macronix International Co., Ltd.

(21) Appl. No.: 10/719,759

(22) Filed: Nov. 20, 2003

(51) Int. Cl. C23C 14/32

(52) U.S. Cl. 204/192.15; 204/192.12

(57) ABSTRACT

A method of improving thermal stability for cobalt salicide includes providing a substrate which has a silicon layer formed thereon. A cobalt layer is formed over the silicon layer, and TiNₓ layer is formed over the cobalt layer. The TiNₓ layer includes x atoms of nitrogen for each atom of titanium in a TiNₓ molecule, and a value of x is greater than 0.9. A first thermal process is then performed to form a cobalt salicide layer over the silicon layer. Any non-reactive cobalt is removed, and a second thermal process is performed to enhance the conductivity of the cobalt salicide layer.

### BACKGROUND OF THE INVENTION

1. Field of the Invention

The present invention relates generally to semiconductor fabrication and, more particularly, to a method for forming cobalt salicide having improved thermal stability.

2. Description of the Related Art

In the field of semiconductor manufacturing, design innovation is constantly challenged by manufacturing implementation. Theoretical possibilities evolve into components, assemblies, and products only as fast as manufacturing limitations can be overcome.

By way of example, processor performance continues to improve as dimension decreases. A decrease in dimension of a processor leads to an increase in transistor density, which increases device speed due to, among other things, shorter carrier transit. The ever-shrinking scale of processor dimension, however, presents significant challenges including, by way of example, vertical scaling of junctions and gate dielectrics, and advanced interconnect to minimize RC delay.

As is known, polycide and silicided junctions are used at the gate and diffusion level to reduce parasitic resistance. The self-aligned silicide (also referred to as “salicide”) on the gate and source/drain reduces parasitic resistance, but line width limitations challenge implementation in smaller and smaller features and devices. One type of salicide that has proven particularly effective has been cobalt salicide. Cobalt is regarded as a useful material in self-aligned salicide processing because of its low resistance and its silicon compatible lattice structure. Cobalt and cobalt salicide (CoSi₂), however, can penetrate into the junction area, resulting in junction leakage, increase in contact resistance, and deteriorating transistor current drive. Generally, high temperatures are required for reacting cobalt and silicon, and a significant portion of the silicon substrate gets consumed in the process, causing the undesirable changes in the gate junction depth. Therefore, in conventional semiconductor manufacturing processes, cobalt salicide processing is typically only used in mid- and back-end processes to avoid process temperatures that are too high. In some conventional applications, a titanium (Ti) or a titanium nitride (TiN) layer is formed on the cobalt layer to avoid cobalt oxidation, but thermal stability remains a challenge.

In consideration of the foregoing, what is needed is a method of improving the thermal stability of cobalt salicide to enable use of desirable cobalt salicide processes in front-end processing.

### SUMMARY OF THE INVENTION

Broadly speaking, the present invention fills this need by providing cobalt salicide having improved thermal stability. The present invention can be implemented in numerous ways, including as a process, an apparatus, a system, a device, or a method. Several embodiments of the present invention are described below.

In one embodiment, a method of improving the thermal stability for cobalt salicide is provided. In this method, a substrate having a silicon layer formed thereon is provided. A cobalt layer is formed over the silicon layer, and a TiNₓ layer is formed over the cobalt layer. The method further includes performing a first thermal process to form a cobalt salicide layer over the silicon layer, and then removing a non-reactive cobalt layer. The TiNₓ layer includes x atoms of nitrogen for each atom of titanium in a TiNₓ molecule, and the value of x is greater than 0.9.

In another embodiment, a method of forming cobalt salicide is provided. As used herein, the phrase “cobalt salicide” refers to self-aligned cobalt silicide, i.e., cobalt silicide formed by a self-aligning process. The method includes forming a layer of silicon, forming a layer of cobalt over the layer of silicon, and forming a layer of TiNₓ over the layer of cobalt, with the value of x being greater than 0.9. The method further includes performing a first thermal process to form a layer of cobalt salicide over the layer of silicon.

The advantages of the present invention over the prior art are numerous. One notable benefit and advantage of the invention is that in embodiments of the present invention, N atoms of the TiNₓ layer diffuse into the cobalt salicide layer, and the N atoms suppress cobalt salicide grains from collecting together during the thermal processes. A higher x ratio of TiNₓ, that is, a higher ratio of Nₓ atoms to Ti atoms in each molecule of TiNₓ, achieves better performance. Therefore, the thermal stability of the cobalt salicide can be improved. With an improved thermal stability of the cobalt salicide, the cobalt salicide process can be used in front-end fabrication processes.

Other advantages of the invention will become apparent from the following detailed description, taken in conjunction with the accompanying drawings, illustrating by way of example the principles of the invention.

### BRIEF DESCRIPTION OF THE DRAWINGS

The accompanying drawings, which are incorporated in and constitute part of this specification, illustrate exemplary embodiments of the invention, and together with the description serve to explain the principles of the invention.

FIG. 1 shows a cross section of a semiconductor substrate in the process of being fabricated in accordance with one embodiment of the present invention.

FIG. 2 shows a cross section of the semiconductor substrate, formed of the semiconductor substrate illustrated in FIG. 1, following a first thermal process, in accordance with one embodiment of the invention.

FIG. 3 shows a cross section of a semiconductor substrate as formed by the removal of the non-reactive Co layer and the TiNₓ layer in accordance with an embodiment of the present invention.

FIG. 4 shows a flow chart diagram illustrating the method operations performed to improve the thermal stability for cobalt salicide, in accordance with one embodiment of the present invention.

FIG. 5 illustrates a front-end process application of cobalt salicide formed in accordance with one embodiment of the present invention.

### DETAILED DESCRIPTION OF THE PREFERRED EMBODIMENTS

A method to improve the thermal stability of cobalt salicide is described. In one embodiment, the method includes formation of a TiNₓ layer over a cobalt layer prior to the thermal process to form the cobalt salicide. N atoms diffuse into the cobalt resulting in an improved thermal stability and enabling front-end implementation of cobalt salicide processes. In the following description, numerous specific details are set forth in order to provide a thorough understanding of the present invention. It will be understood, however, to one skilled in the art, that the present invention may be practiced without some or all of these specific details. In other instances, well known process operations have not been described in detail to avoid obscuring the present invention unnecessarily.

As an overview, in one embodiment, a substrate having a silicon layer thereon is provided. A cobalt layer is formed on the silicon layer, and a TiNₓ layer is formed on the cobalt layer. In one embodiment, the value of x is greater than 0.9. A thermal process is performed to form a cobalt salicide layer, and the non-reactive cobalt layer is removed.

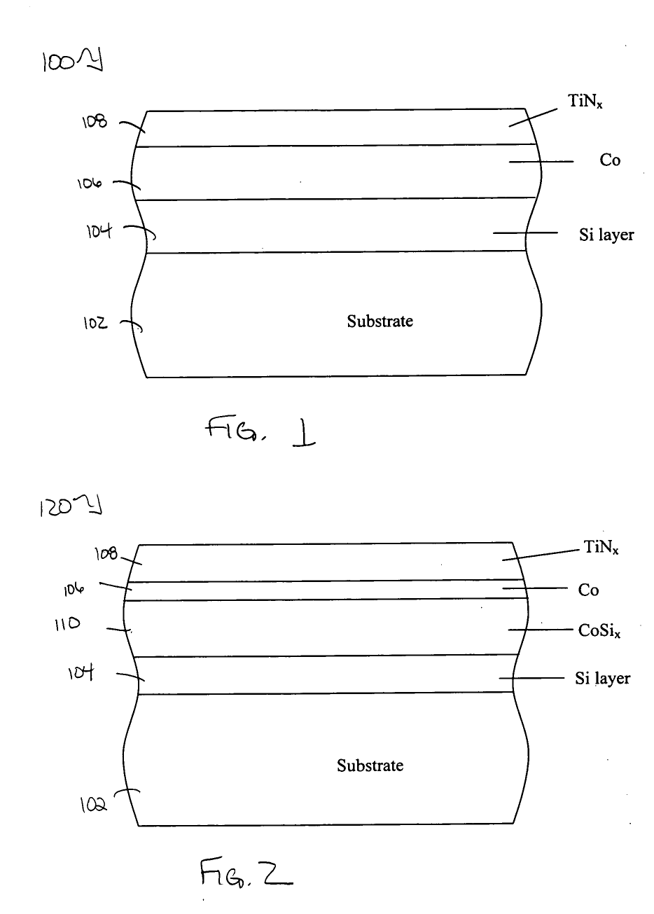

FIG. 1 shows a cross section of a semiconductor substrate 100 in the process of being fabricated in accordance with one embodiment of the present invention. As shown in FIG. 1, the semiconductor substrate 100 includes a substrate layer 102. The substrate layer 102 includes any and all previously fabricated layers or levels and features of the semiconductor substrate 100. As is known, semiconductor devices such as transistors, memory cells, etc., are typically fabricated as multi-layer structures, many of which are often interconnected. As shown in FIG. 1, the substrate layer 102 is representative of any and all previously fabricated multiple-layer structures.

A silicon (Si) layer 104 is deposited over the substrate layer 102. In one embodiment, the Si layer 104 provides a base layer or level in which source/drain regions, gate features, junctions, etc. are fabricated. In the illustrated embodiment, a cobalt (Co) layer 106 is deposited over the Si layer 104, and a TiNₓ layer 108 is deposited over the Co layer 106.

In one embodiment, the TiNₓ layer 108 is formed using a sputtering process, and the gas used in the sputtering process comprises N₂ and Ar. In one embodiment, the ratio of N₂ to Ar is approximately 3:1. Additionally, the thickness of the formed TiNₓ layer 108 should not to be too thick, and is preferably set between about 25 angstroms and about 100 angstroms.

In one embodiment, a first thermal process is performed to form a cobalt salicide layer. During the first thermal process, N atoms of the TiNₓ layer 108 diffuse into the Co layer 106. Because the TiNₓ layer 108 is formed to a thickness of between about 25 angstroms and about 100 angstroms, a smaller amount of the Ti of the TiNₓ layer 108 diffuses into the Si layer 104 to form TiSiₓ. As is known, both the thermal stability and the resistance of TiSiₓ are poor.

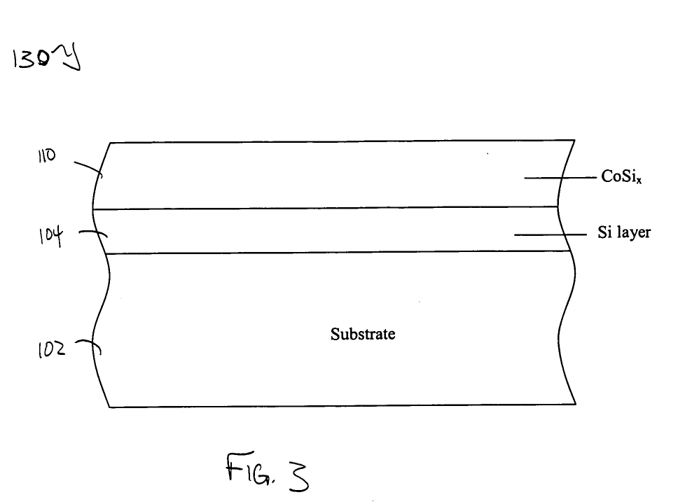

FIG. 2 shows a cross section of the semiconductor substrate 120, formed of the semiconductor substrate 100 illustrated in FIG. 1, following a first thermal process, in accordance with one embodiment of the invention. In the illustrated embodiment, the substrate layer 102 remains essentially unchanged. The Si layer 104 thins during thermal processing, and the new CoSiₓ layer 110 is formed. The CoSiₓ layer 110 is described in greater detail below. Over the CoSiₓ layer 110 remains a layer of unreacted Co 106, and the TiNₓ layer 108.

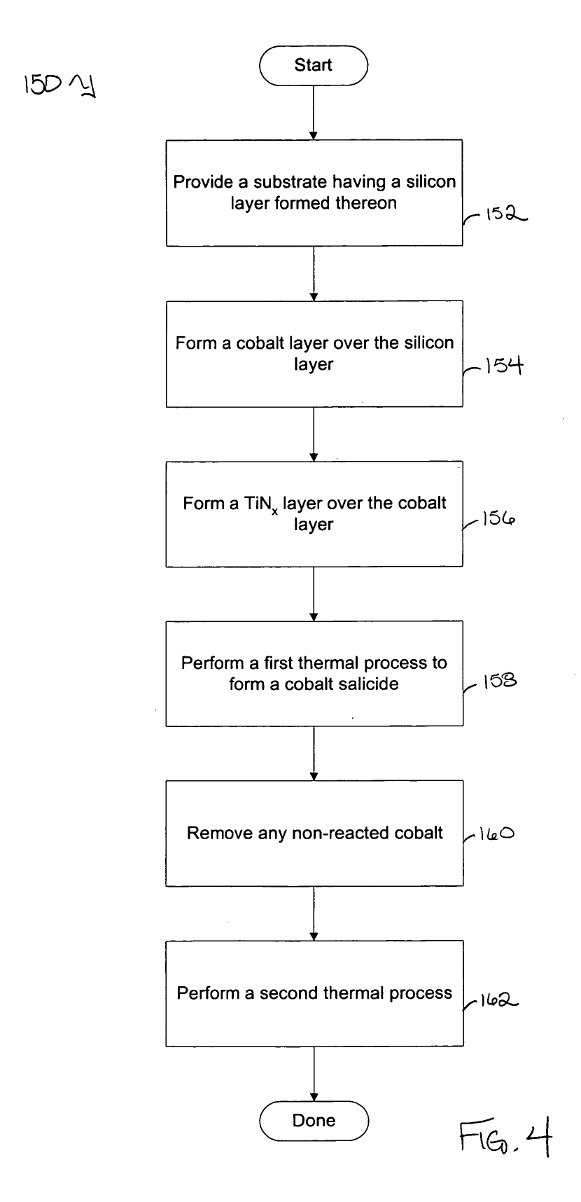

In one embodiment, a next process is performed, following the first thermal process described above, to remove the non-reactive Co layer 106 and the TiNₓ layer 108. FIG. 3 shows a cross section of a semiconductor substrate 130 as formed by the removal of the non-reactive Co layer 106 and the TiNₓ layer 108 (see FIG. 2) in accordance with an embodiment of the present invention. The resulting semiconductor substrate includes a substrate layer 102, an Si layer 104, and a CoSiₓ layer 110.

In one embodiment, a second thermal process is performed to enhance the conductivity of the cobalt salicide (CoSiₓ) layer 110. In the second thermal process, the Co₂Si or CoSi formed during the first thermal processing would change to CoSi₂, and the resistance of the cobalt salicide would be decreased.

In embodiments of the present invention, nitrogen (N) atoms in the TiNₓ layer 108 (see FIG. 2) diffuse into the cobalt (Co) 106 and cobalt salicide (CoSiₓ) layers 110 (see FIG. 2). If N atoms of the TiNₓ layer 108 were not permitted or induced to diffuse into the cobalt salicide (CoSiₓ) layer 110, the cobalt salicide grains collect to form larger grains in initial and subsequent thermal processes. These larger grains do not connect together within the cobalt salicide layer, and the large, unconnected grains cause poor conductivity of the typically formed cobalt salicide layer.

In embodiments of the present invention, however, N atoms of the TiNₓ layer 108 (see FIG. 2) diffuse into the cobalt salicide layer 110 and suppress the cobalt salicide grains from collecting together. Therefore, the conductivity of the cobalt salicide formed in accordance with the principles described herein is improved.

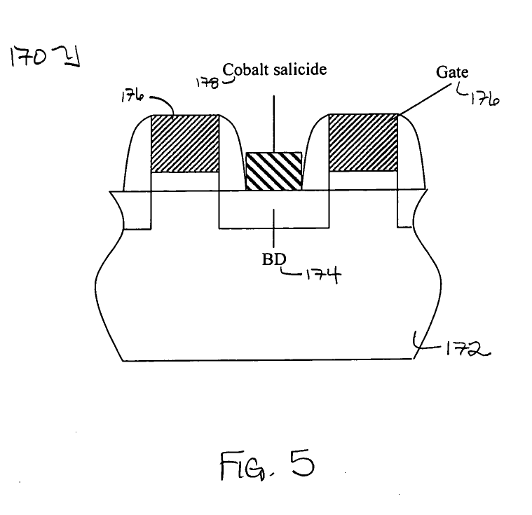

FIG. 4 shows a flow chart diagram 150 illustrating the method operations performed to improve the thermal stability for cobalt salicide, in accordance with one embodiment of the present invention. The method begins with operation 152 in which a substrate is provided. In one embodiment, the substrate has a silicon layer formed thereon. The substrate can be of any size and type compatible and useful for typical operations in which cobalt salicide is an appropriate and useful feature. Typical substrate sizes include 200 mm and 300 mm silicon wafers used in semiconductor manufacturing, and additional sizes and materials used in the fabrication of flat panel display features, hard disk drive features, MEMS, etc. The silicon layer can be a first layer in the fabrication of features in the substrate, or the substrate can have from one to a plurality of layers of features or structures, being fabricated therein, and the silicon layer forms, in one embodiment, a base layer for the fabrication of a multi-layer structure on the substrate.

The method continues with operation 154 in which a cobalt layer is formed over the silicon layer. Embodiments of the present invention provide for improved thermal stability of cobalt salicide, and in operation 154, the cobalt layer to be silicided (or “salicided” in the case of a self-aligned process) is formed over the silicon layer.

Next, in operation 156, a TiNₓ layer is formed over the cobalt layer. In one embodiment of the invention, the N atoms of the TiNₓ layer will diffuse into the cobalt salicide layer formed during the first thermal processing described below. The N atoms suppress the cobalt salicide grains from collecting together during thermal processing, improving the thermal stability of the cobalt salicide.

The TiNₓ layer is formed, in one embodiment, with the value of x being larger than 0.9. In one embodiment, the TiNₓ layer is formed by a sputtering process. In a further embodiment, the sputtering process is accomplished with a gas consisting of N₂ and Ar. In one embodiment, the N₂ and the Ar in the sputtering gas are provided in concentrations at a ratio of approximately 3:1. In one embodiment, the TiNₓ layer is formed to a thickness in a range of approximately 25 angstroms to approximately 100 angstroms.

The method continues with operation 158 in which a first thermal process is performed in the formation of cobalt salicide. The thermal process may be any known thermal process, however, in the present invention, the increased thermal stability of the cobalt results in formation of cobalt salicide without undesirable side effects such as substantial cobalt penetration into silicon and into gate/junction regions.

In operation 160, any non-reacted cobalt is removed. In one embodiment, once any non-reacted cobalt has been removed in operation 160, the method concludes with operation 162 in which a second thermal process is performed. In one embodiment, a second thermal process is performed as shown in operation 162 to enhance the conductivity of the cobalt salicide layer. In the second thermal process, Co₂Si or CoSi are converted to CoSi₂, and the resistance of the cobalt salicide is decreased.

Embodiments of the present invention provide for improved thermal stability of cobalt salicide. In contrast with the conventional formation of cobalt salicide in which process temperatures are so high as to decrease the conductivity of the cobalt salicide and dictate only mid- and back-end process applications, the cobalt salicide layer in embodiments of the present invention can be used in the front-end process, such as applying self-aligned cobalt silicide, i.e., cobalt salicide, on the buried source and drain of memory structures. In more detail, the cobalt salicide layer can be formed on the buried source and drain to improve the resistance.

FIG. 5 illustrates a front-end process application of cobalt salicide formed in accordance with one embodiment of the present invention. In FIG. 5, a cobalt salicided feature 170 is shown. In a substrate 172, a buried source and drain (BD) 174 has been formed. The substrate 172 can be an initial layer of a semiconductor wafer, or the substrate 172 can be a layer over one or more fabricated features of multi-layer structures. Typically, the layer over one or more fabricated features of a multi-layer structure is fabricated of silicon or any other desired inter-layer dielectric material. A gate feature 176 is shown fabricated over and adjacent to the buried source and drain 174, and cobalt salicide 178 is shown formed over the buried source and drain 174 to improve the resistance of the junction.

In summary, the present invention provides a method for increasing the thermal stability of cobalt salicide during the formation of cobalt salicide in a plurality of applications. The invention has been described herein in terms of several exemplary embodiments. Other embodiments of the invention will be apparent to those skilled in the art from consideration of the specification and practice of the invention. The embodiments and preferred features described above should be considered exemplary, with the scope of the invention being defined by the appended claims and their equivalents.

1. A method of improving a thermal stability for cobalt salicide, comprising:
providing a substrate having a silicon layer thereon;
forming a cobalt layer over the silicon layer;
forming a TiNₓ layer over the cobalt layer;
performing a first thermal process to form a cobalt salicide layer over the silicon layer; and
removing a non-reactive cobalt layer,
wherein the TiNₓ layer includes x atoms of nitrogen for each atom of titanium in a TiNₓ molecule, and a value of x is greater than 0.9.

2. The method of claim 1, further comprising:
performing a second thermal process,
wherein the second thermal process is performed after the removing of the non-reactive cobalt layer.

3. The method of claim 1, wherein the TiNₓ layer is formed by a sputtering process.

4. The method of claim 3, wherein a gas used in the sputtering process comprises N₂ and Ar.

5. The method of claim 4, wherein a ratio of N₂ to Ar in the gas used in the sputtering process is approximately 3:1.

6. The method of claim 1, wherein the TiNₓ layer is formed to a thickness in a range of approximately 25 angstroms to approximately 100 angstroms.

7. A method of forming cobalt salicide, comprising:
providing a layer of silicon;
forming a layer of cobalt over the layer of silicon;
forming a layer of TiNₓ over the layer of cobalt, wherein a value of x is greater than 0.9; and
performing a first thermal process to form a layer of cobalt salicide over the layer of silicon.

8. The method of claim 7, further comprising:
removing a layer of non-reactive cobalt; and
performing a second thermal process, the second thermal process being performed to decrease a resistance of cobalt salicide formed in the performing of the first thermal process.

9. The method of claim 7, wherein the forming of the layer of TiNₓ is by a sputtering process.

10. The method of claim 9, wherein the sputtering process is accomplished with a gas comprised of N₂ and Ar.

11. The method of claim 10, wherein the ratio of N₂ to Ar in the gas comprised of N₂ and Ar is approximately 3:1.

12. The method of claim 1, wherein the TiNₓ layer is formed to a thickness in a range of approximately 25 angstroms to approximately 100 angstroms.

13. A method for forming cobalt salicide having improved thermal stability, comprising:
providing a silicon layer, the silicon layer being one of a substrate formed of silicon and a layer of silicon formed over a substrate;
forming a cobalt layer over the silicon layer;
forming a TiNₓ layer over the cobalt layer, wherein a value of x is greater than 0.9;
performing a first thermal process, the first thermal process reacting the cobalt layer to form a layer of cobalt salicide;
removing any unreacted cobalt; and
performing a second thermal process to reduce a resistance of cobalt salicide formed in the performing of the first thermal process.

14. The method of claim 13, wherein the TiNₓ layer is formed over the cobalt layer by performing a sputtering process.

15. The method of claim 14, wherein the sputtering process is performed with a gas comprising N₂ and Ar.

16. The method of claim 15 where the ratio of N₂ to Ar in the gas comprising N₂ and Ar is approximately 3:1.

17. The method of claim 13, wherein the TiNₓ layer is formed over the cobalt layer to a thickness in a range of approximately 25 angstroms to approximately 100 angstroms.
